(19) United States
(12) Patent Application Publication
(10) Pub. No.: US 2015/0067437 A1
(43) Pub. Date: Mar. 5, 2015

(54) APPARATUS, METHOD AND SYSTEM FOR REPORTING DYNAMIC RANDOM ACCESS MEMORY ERROR INFORMATION

(71) Applicants: Kuljit S. Bains, Olympia, WA (US); John B. Halbert, Beaverton, OR (US)

(72) Inventors: Kuljit S. Bains, Olympia, WA (US); John B. Halbert, Beaverton, OR (US)

(21) Appl. No.: 14/133,288

(22) Filed: Dec. 18, 2013

Related U.S. Application Data
(60) Provisional application No. 61/872,245, filed on Aug. 30, 2013.

(51) Int. Cl. H03M 13/05

(52) U.S. Cl. CPC H03M 13/05
USPC 714/758

(57) ABSTRACT

Techniques and mechanisms for providing state information describing one or more data errors detected locally at a memory device. In an embodiment, the memory device includes a memory core and error detection circuit logic configured to detect for errors of data stored by the memory core. A die of the memory device includes both the memory core and the error detection circuitry. In another embodiment, state information is stored in a mode register of the memory device in response to the error detection logic detecting an occurrence of a data error. The state information is available for access by a memory controller or other agent which is external to the memory device.

### RELATED APPLICATIONS

This application is a nonprovisional application based on U.S. Provisional Patent Application No. 61/872,245 filed Aug. 30, 2013, and claims the benefit of priority of that provisional application. Provisional Application No. 61/872,245 is hereby incorporated by reference.

### BACKGROUND

1. Technical Field

Embodiments of the invention generally relate to the field of integrated circuits and more particularly, but not exclusively, to a communication of error detection information for a memory device.

2. Background Art

Memory devices are susceptible to errors such as transient (or soft) errors. If these errors are not handled properly, they can cause a computing system to malfunction. Redundant information in the form of error correcting codes (ECCs) can be used to improve overall system reliability. Typically, a memory controller performs error correction coding operations to generate and/or evaluate such redundant information for a plurality of data bits.

The redundant information is often stored in the memory with the corresponding plurality of data bits to allow the memory controller to recover the plurality of data bits if errors are introduced in one or more of the plurality of data bits during transmission to/from the memory or while being stored in the memory. The redundant information, however, increases the storage requirement of the memory system and, thereby, increases the cost of the memory system. Thus, ECC is typically used for comparatively high-end or mission critical applications.

### BRIEF DESCRIPTION OF THE DRAWINGS

The various embodiments of the present invention are illustrated by way of example, and not by way of limitation, in the figures of the accompanying drawings and in which:

FIG. 1 is a block diagram illustrating elements of a system for exchanging data error information according to an embodiment.

FIG. 2A is a flow diagram illustrating elements of a method for operating a memory device according to an embodiment.

FIG. 2B is a flow diagram illustrating elements of a method for controlling a memory device according to an embodiment.

FIG. 3 is a block diagram illustrating elements of a memory device for providing data error information according to an embodiment.

FIG. 4 is a diagram illustrating elements of mode registers for providing data error information according to an embodiment.

FIG. 5 is a block diagram illustrating elements of a computing system for communicating data error information according to an embodiment.

FIG. 6 is a block diagram illustrating elements of a mobile device for communicating error information according to an embodiment.

### DETAILED DESCRIPTION

Embodiments discussed herein variously provide techniques or mechanisms for a memory controller (or other agent) external to a memory device to be able to detect and/or evaluate one or more data errors which the memory device detects locally. The memory device may include a memory core and error detection circuit logic which, for example, includes or couples to error correction logic of the memory device. The error detection logic may detect for errors of data stored by the memory core—e.g. where an integrated circuit die (for brevity, referred to herein as a ‘die’) the memory device includes both the memory core and the error detection circuitry. In an embodiment, state information is stored by the memory device—e.g. in a mode register of the memory device—in response to the error detection logic detecting an occurrence of a data error. The state information may be available for access by an agent which is external to the memory device. Such access may provide for improved insight into memory operation and improved management of such operation.

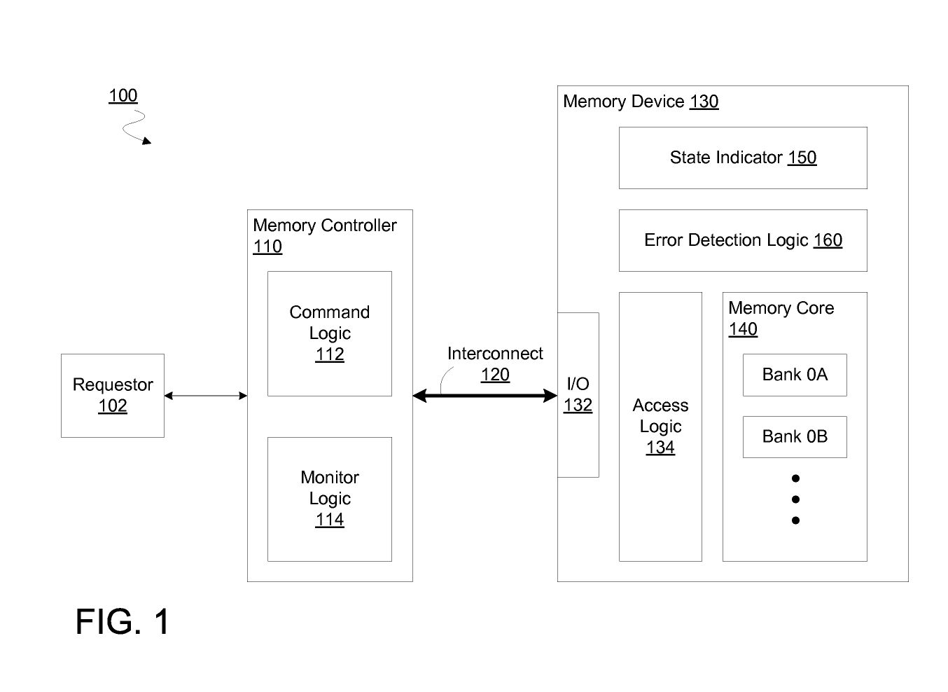

FIG. 1 illustrates elements of a system 100 implemented according to an embodiment. System 100 represents any of a number of computing systems that may include memory which supports error detection functionality. Such computing systems may include servers, desktops, laptops, mobile devices, smartphones, gaming devices, and others.

System 100 may include a memory device 130 coupled to a memory controller 110 via an interconnect 120—e.g. where memory controller 110 is to control, at least in part, a transfer of information between a requester 102 and memory device 130. Requester 102 may be a processor (e.g., a central processing unit and/or a core), a service processor, an input/output device (e.g., a peripheral component interconnect (PCI) Express device), memory itself, or any other element of system 100 that requests access to memory. In some embodiments, memory controller 110 is on the same die as requester 102.

Memory device 130 may include any of a variety of types of memory technology that, for example, have rows of memory cells, where data is accessible via a wordline or the equivalent. In one embodiment, memory device 130 includes dynamic random access memory (DRAM) technology such as that which operates according to a Dual Data Rate (DDR) specification, a Low Power DDR (LPDDR) specification or other such memory standard.

Memory device 130 may be an integrated circuit package within a larger memory device (not shown) of system 100. For example, memory device 130 may be a DRAM device of a memory module such as a dual in-line memory module (DIMM).

Memory device 130 may include a memory core 140, which represent one or more logical and/or physical groups of memory. An example of one such grouping of memory is a bank of memory resources which, for example, may include an array of storage elements arranged in rows and columns. By way of illustration and not limitation, portions of memory core 140 may include (e.g. be configured to operate as) one or more banks, as represented by the illustrative banks 0A, 0B.

Memory device 130 may include access logic 134 to facilitate, at least in part, access to memory core 140—e.g. where such access is provided for servicing one or more commands from memory controller 110. Access logic 134 may include, or operate in conjunction with, logic of memory device 130 which provides resource access according to conventional techniques. By way of illustration and not limitation, access logic 134 may include or couple to column logic and/or row logic (not shown) which are used to decode an access instruction to the proper memory location within memory core 140.

In an embodiment, memory controller 110 may send commands or instructions to memory device 130 over one or more buses, as represented by the illustrative interconnect 120 coupling I/O circuitry 132 of memory device 130 to memory controller 110 and/or one or more other memory devices (not shown). Such commands may be interpreted by memory device 130—e.g. including access logic 134 decoding command information to perform a variety of access functions within the memory and/or decoding address information with column logic and/or row logic. For example, such logic may access a specific location in memory core 140 with a combination of a column address strobe or signal (CAS) and a row address strobe or signal (RAS). Rows of memory may be implemented in accordance with known memory architectures or their derivatives. Briefly, a row of memory core 140 may include one or more addressable columns of memory cells, as identified by the CAS generated by column logic of memory device 130. The rows may each be variously addressable via the RAS generated by row logic of memory device 130. Access to memory core 140 may be for the purpose of writing data exchanged (and/or reading data to be exchanged) via a data bus which, for example, is included in interconnect 120.

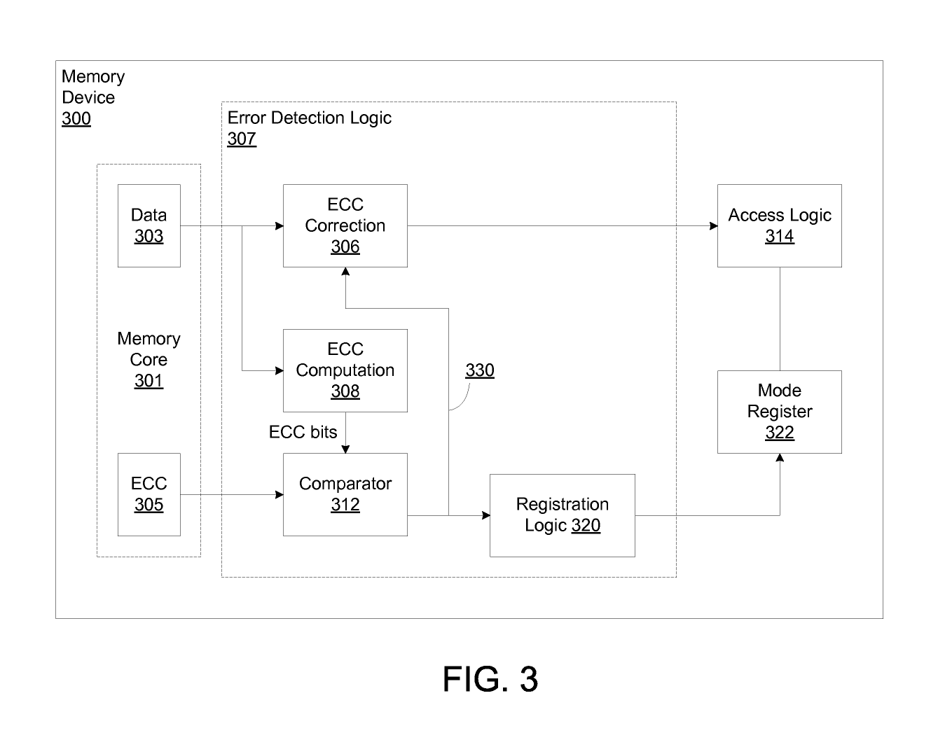

Memory device 130 may store data bits and, in an embodiment, further store corresponding error check bits—e.g., error correction code (ECC) bits—for such data bits in memory core 140. Memory device 130 may also include on-die error detection logic 160. In some embodiments, error detection logic 160 enhances the reliability, availability, and serviceability (RAS) of memory device 130. More particularly, in some embodiments, error detection logic 160 enables memory device 130 to identify whether one or more of data bits have been corrupted based on corresponding error check bits which, for example, may also be stored in memory device 130. In some embodiments, error detection logic 160 includes, for example, ECC computation logic and comparison logic. An example of such error detection logic according to one embodiment is further discussed below with reference to FIG. 3. This computation and comparison logic may enable memory device 130 to locally compute ECC bits for data—e.g. during a read of such data—and to compare the locally computed ECC bits with stored ECC bits. If the locally computed ECC bits do not match the stored ECC bits, then error detection logic 160 may store state information which is is descriptive or otherwise indicative of the data error represented by such a mismatch. In the illustrated embodiment, memory device 130 includes a state indicator 150 to store state information related to such a data error. In some embodiments, state indicator 150 includes one or more bits of a register—such as that of a mode register set (MRS)—which may be read by memory controller 110.

For example, memory controller 110 includes command logic 112—e.g. including any of a variety of hardware logic and/or executing software logic—to send commands via interconnect 120. Command logic 112 may include or couple to logic of memory controller which performs operations to generate, transmit or otherwise determine commands which are sent according to one or more conventional techniques. By way of illustration and not limitation, command logic 112 and/or monitor logic 114 may supplement otherwise conventional command/address signaling functionality which, for example, conforms to some or all requirements of a dual data rate (DDR) specification such as the DDR3 SDRAM JEDEC Standard JESD79-3C, April 2008 or the like.

Monitor logic 114 may comprise circuitry and/or executing software to detect and/or otherwise evaluate data error events detected by error detection logic 160. Thus, monitor logic 114 enables memory controller 110 to monitor, track, and possibly store information describing data errors which are detected (and in an embodiment, corrected) external to memory controller 110. By way of illustration and not limitation, such data error event might otherwise be transparent to memory controller 110, but for functionality variously provided by certain embodiments.

By way of illustration and not limitation, command logic 112 may send to memory device 130 a command (e.g. a mode register GET command) to read state information stored in state indicator 150. Such a command may be sent by memory controller 110 in response to one or more signals indicating that memory device 130 has internally (locally) detected one or more data errors. In response to such a command, monitor logic 114 may receive address information, error count information, error rate information and/or any of a variety of other types of state information stored in state indicator 150 based on operations of error detection logic 160. In an embodiment, monitor logic 114 enables memory controller 110 to adapt memory management techniques based upon such error detection information.

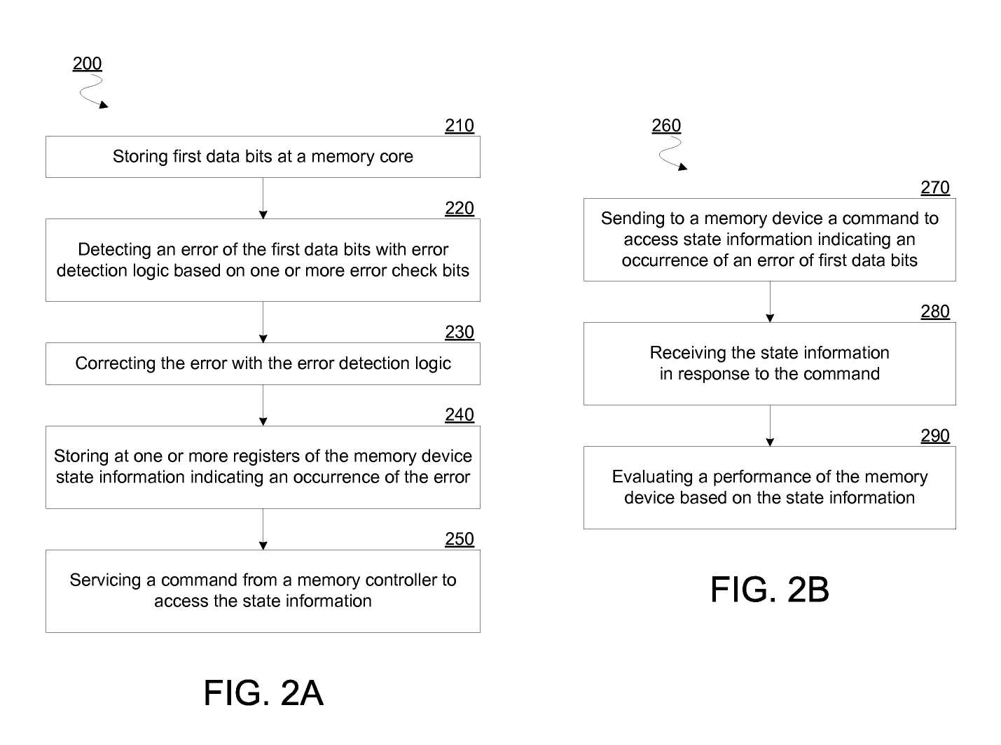

FIG. 2A illustrates elements of a method 200 for operating a memory device according to an embodiment. Method 200 may be performed by a memory including some or all of the features of memory device 130, for example.

In an embodiment, method 200 includes, at 210, storing first data bits at a memory core. The storing at 210 may include, for example, storing data bits in volatile memory cells of a DRAM. Although certain embodiments are not limited in this regard, the memory core may further store one or more error check bits (e.g. including a parity value, ECC value or the like) which correspond to the first data bits. Such one or more error check bits may be calculated—e.g. by the memory device, or a memory controller coupled thereto, during or prior to storing of the first data bits—to serve as a reference for subsequent data error detection. In some embodiments, such one or more error check bits are instead stored in a memory core (e.g. on a different integrated circuit die) other than the one storing the first data bits.

Method 200 may further comprise, at 220, detecting an error of the first data bits with error detection logic of the memory device. The detecting may be performed at 220 based on the one or more error check bits corresponding to the first data bits. In an embodiment, a die of the memory device includes both the memory core and the error detection logic.

In response to error detected at 220, method 200 may perform, at 230, correcting the error with the error detection logic. The correcting at 230 may include the error detection logic calculating a corrected version of the first data bits. Such calculating may include operations adapted from any of a variety of conventional error correction techniques which, to avoid obscuring features of certain embodiments, are not discussed herein.

Method 200 may further perform, at 240, storing at one or more registers of the memory device state information indicating an occurrence of the error. In an embodiment, the state information is distinguished from the corrected version of the first data bits. For example, the first data bits may be stored at a first memory location of the memory core, wherein the state information includes address information corresponding to the first memory location. By way of illustration and not limitation, such address information may include bank address information, row address information, column address information and/or the like. Alternatively or in addition, the state information may include an updated count of errors.

In an embodiment, method 200 further comprises, at 250, servicing a command from a memory controller to access the state information. In an embodiment, the servicing of the command at 250 is performed after the storing of state information at 240. For example, the state information may be stored at 240 prior to, or otherwise independent of, the memory device receiving the command from the memory controller. Servicing the command at 250 may include, for example, sending the state information from the memory device to the memory controller. Alternatively or in addition, servicing the command at 450 may include resetting a count of errors to a default value—e.g. zero (0).

In some embodiments, method 400 further comprises sending one or more signals from the memory device, the one or more signals to indicate to a memory controller that the memory device has internally detected one or more data errors. The command serviced at 250 may be received by the memory device in response to the one or more signals. Such one or more signals may be communicated via a signal line which is dedicated to communicating such an error indication signal. Alternatively, the one or more signals may be received via a signal line which also provides other signal functionality. For example, such a signal line may include a data bus inversion (DBI) signal line, a data mask (DM) signal line, or the like.

FIG. 2B illustrates elements of a method 260 for controlling a memory device according to an embodiment. Method 260 may be performed with a memory controller which, for example, has some or all of the features of memory controller 110. In an embodiment, performance of method 260 controls a memory device which provides functionality to perform method 200.

In an embodiment, method 260 includes, at 270, sending from the memory controller to a memory device a command to access state information. Such a command may be sent at 270 in response to the memory controller receiving from the memory device—e.g. with a signal line of interconnect 120—one or more signals to indicate that the memory device has locally detected (and, optionally, corrected) one or more data errors. The one or more signals may be received, for example, via a signal line which is dedicated to communicating such an error indication signal. Alternatively, the one or more signals may be received via a signal line which also provides other signal functionality. For example, such a signal line may alternatively be used at other times to communicate a DBI state, a DM state or other such types of information.

The command may be sent at 270 to access state information indicating an occurrence of an error of first data bits stored by a memory core of the memory device. The state information may be stored at one or more registers of the memory device—e.g. in response to detection of the error by error detection logic of the memory device. Such detection may be based on one or more error check bits corresponding to the first data bits. The state information may be distinguished, for example, from corrected first data bits which the error detection logic calculates to correct the error. In an embodiment, a die of the memory device includes both the memory core and the error detection logic

Method 260 may further include, at 280, receiving the state information from the memory device in response to the command sent at 270. The state information may include address information corresponding to a memory location of the memory core. For example, the state information may include a bank address, row address, column address and/or other information for a memory location where the first data bits are (or were) stored. Alternatively or in addition, the state information may include a count of data errors variously detected (and, in some embodiments, variously corrected) locally at the memory device.

In an embodiment, method 200 further comprises, at 290, evaluating a performance of the memory device based on the state information. For example, the evaluating at 290 may include identifying a current count of data errors, a rate of change (e.g. first order, second order or the like) of such a count of data errors and/or any of a variety of other performance metrics. In some embodiments, the evaluating at 290 includes comparing such a performance metric to an a priori threshold level to determine whether performance metric is within a predetermined range. The memory controller may modify operation of the memory device based on such evaluation. Certain embodiments are not limited with respect to particular operational modifications made in response to the evaluating at 490.

FIG. 3 is a block diagram illustrating selected aspects of a memory including on-die error detection logic, according to an embodiment of the invention. In some embodiments, memory device 300 (e.g., a DRAM) includes, inter alia, memory core 301 and error detection logic 307. Memory core 301 and error detection logic 307 may be integrated onto a common chip. In an embodiment, memory device 300 includes some or all of the features of memory device 130—e.g. where memory core 301 and error detection logic 307 correspond functionally to memory core 140 and error detection logic 160, respectively.

At a given point during operation of memory device 300, memory core 301 may store data bits 303 and, in some embodiments, further store corresponding ECC bits 305. Bits 303, 305 may both be stored, for example, in a common memory resource of memory core 301 such as a single row bank, page and/or the like—e.g. where bits 303, 305 are stored in the same addressable memory location. Alternatively, bits 303, 305 may be stored in different respective resources of memory core 301. Storage of bits 303, 305 may be include operations adapted from any of a variety of conventional techniques for storing data and corresponding error check bits. Such conventional techniques are not discussed in detail herein, and are not limiting on certain embodiments.

In some embodiments, ECC bits 305 are computed locally by memory device 300—e.g. with error detection logic 307. Alternatively, ECC bits 305 may be computed by a host (e.g., memory controller 110, shown in FIG. 1) and provided to memory device 300 in a write data frame. Error detection logic 307 includes logic to check for and, in certain embodiments, correct data errors. In the illustrated embodiment, error detection logic 307 includes ECC correction logic 306, ECC computation logic 308, comparator 312. In alternative embodiments, error detection logic 307 may include more elements, fewer elements, and/or different elements. In addition, in some embodiments, one or more of the elements illustrated as being part of error detection logic 307 may be implemented in a different part memory device 300.

ECC computation logic 308 computes ECC bits to cover data 303. In some embodiments, logic 308 uses the same polynomial to compute the ECC bits as was used to compute ECC bits 305. For example, logic 308 may use the same polynomial as error check logic of a memory controller (not shown) controlling memory device 300. Logic 308 may use almost any error correction code polynomial. By way of illustration and not limitation, logic 308 may compute 8 ECC bits to cover 64 data bits. In alternative embodiments, the number of ECC bits and/or data bits may be different.

Comparator 312 compares the computed ECC bits generated by logic 308 with the stored ECC bits (e.g., ECC bits 305). If the two sets of ECC bits match, then comparator 312 indicates a MATCH state—e.g. via a signal 330. If the computed ECC bits do not match the stored ECC bits, then data bits 303 may contain an error. In some embodiments, error detection logic 307 includes ECC correction logic 306 to correct certain errors. In such embodiments, if the two sets of ECC bits do not match, then comparator 312 may provide data (e.g., an indication of which ECC bits failed to match) to ECC correction logic 306 so that it can correct the problem. In some embodiments, logic 306 includes single bit correct logic and signal 330 (or other such signal) indicates an ERROR state—e.g. by specifying a single bit that needs to be corrected out of, for example, 64 bits. Although certain embodiments are not limited in this regard, comparator 312 may indicate an ALERT state (e.g. with signal 330) if it detects an error having a weight that logic 306 cannot correct. For example, comparator 312 may indicate an ALERT state if it detects a double bit error. Comparator 312 may be any logic suitable for comparing one set of bits to another and asserting one or more signals in response to the comparison.

As discussed above, ECC correction logic 306 includes logic to correct certain kinds of errors (e.g., single bit errors). In some embodiments, logic 306 receives data bits 303 and MATCH/ERROR/ALERT state information as inputs and outputs a corrected version of data bits where necessary/possible. If no error is detected, then data bits 303 may simply flow through ECC correction logic 306. Alternatively or in addition, ECC correction logic 306 may write corrected data bits back into the location of data 303. For example, such a write-back of corrected data bits may be performed during patrol scrub operations of memory device 300. Memory device 300 may include access logic 314 comprising circuitry to frame data bits from ECC correction logic 306 for transmission to a requester—e.g. via a memory controller. In some embodiments, access logic 314 or other such logic of memory device 300 provides prepares information stored in mode register 322 to be read by a memory controller or other agent coupled to memory device 300.

In an embodiment, detection of a data error by comparator 312 may result in a storing of state information describing or otherwise indicating the data error in one or more mode registers of memory device 300—e.g. as represented by the illustrative mode register 322. For example, comparator 312 may directly or indirectly signal registration logic 320 that a data error is indicated by a mismatch between ECC bits 305 and the ECC bits generated by logic 308 based on data bits 303. In response to such signaling from comparator 312, registration logic 320 may store information from comparator 312, and/or other information describing the detected data error, in a mode register 322. The information stored in mode register 322 may then be accessible to a memory controller and/or other agent which is external to memory device 300. By way of illustration and not limitation, a memory controller may issue a command for a read access of mode register 322 to access address information (e.g. including a row address, column address, bank address and/or the like) for a memory location associated with erroneous data. Such address information may represent an address for a memory location associated with a most recently detected data error prior to the command to access mode register 322.

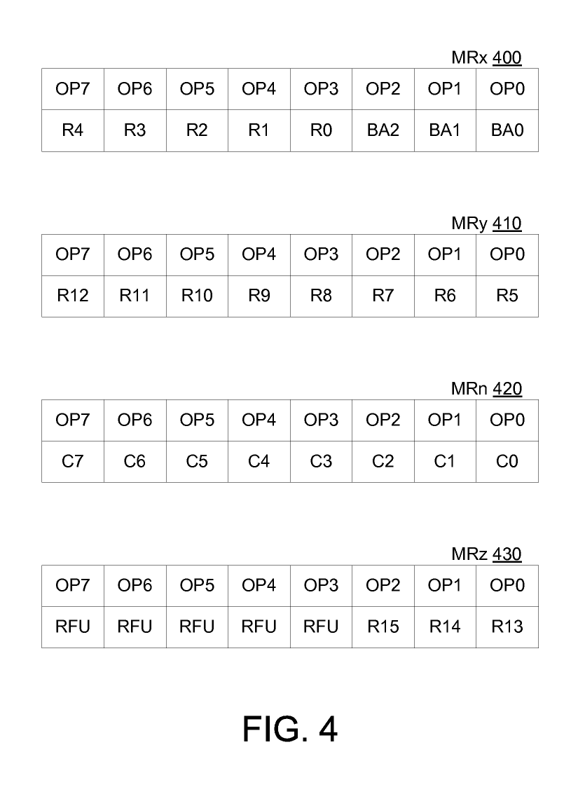

FIG. 4 illustrates elements of various mode registers of a memory device according to an embodiment for storing information indicating a data error. Such mode registers may include some or all of the features of state indicator 150, for example. State information may be stored to such mode registers by registration logic 320 or other such logic—e.g. based on operations of method 200.

In an embodiment, one or more mode registers store captured physical address information for a location in a memory core—e.g. in response to detection of at least one data bit failure at the location. Such captured address information may include a bank address, row address, column address and/or the like. By way of illustration and not limitation, the mode registers shown in FIG. 4 include mode register x (MRx) 400, mode register y (MRy) 410 and mode register z (MRz) 430 of a LPDDR4 synchronous DRAM (SDRAM) or other such memory configured to provide functionality according to an embodiment. Physical address information variously captured by mode registers 400, 410, 430 may include a three bit bank address (BA2-BA0) and a 16 bit row address (R15-R0). In an embodiment, some or all such mode registers may capture a subset of the physical location of the memory location in which at least one bit failure was detected—e.g. in order to limit a total size of the mode registers. For example, the mode registers may only capture address information including a bank address and a row address. As shown, MRz 430 includes five bits that are reserved for further use (RFU). Some or all such RFU bits may be used to store additional or alternative address information—e.g. a 5-bit column address. Mode registers MRx 400, MRy 410 and MRz 430 may be read-only registers, at least with respect to access by a memory controller controlling the memory device.

Some or all of MRx 400, MRy 410 and MRz 430 may store captured physical addresses information for a given data error, where such information is stored until a more recent detection—e.g. a next detection—of a data error. In some embodiments, one or more mode registers store physical addresses information for the Xmost recently detected data errors, where X is an integer greater than one (1). A write to some or all of mode registers may be based on operation of error detection logic 160, for example. Some or all of or all of mode registers 400-430 may be read by memory controller 110 (or other such control logic). In some embodiments, memory controller 110 does not have permission to write to one or more of the mode registers.

For example, the mode registers may further comprise a mode register n (MRn) 420 which can be both read from and written to by such a memory controller. MRn 420 may store an error count which is available to be updated by logic of the memory device and, in some embodiments, to be reset by the memory controller. As shown with MRn 420, counter bits C7-C0 may be updated to store a current total number of detected errors for memory resources including the memory core. Alternatively or in addition, one or more mode registers may store a count of correctable errors and/or an indication whether a logged error—e.g. a most recently detected error—is corrected or uncorrected. A particular bit of a counter—e.g. the C7 bit of MRn 420—may be a sticky bit which, for example, is to be cleared by the memory controller. Such a sticky bit may remain at a particular value once it transitions to that value (e.g. until a reset event), to allow for detection of an overflow of the counter.

In an embodiment, capturing state information associated with an error may be based on whether the error is determined to be correctable or uncorrectable. For example, certain embodiments perform a first capture of state information—e.g. a first capture of a set of such captures—in response to detecting that a first error is an uncorrectable error. Alternatively or in addition, a last capture for such a set of captures may be performed in response to detecting that a second error is a correctable error. Different mode registers may be provided to capture respective state information for a correctable (e.g. corrected) error and an uncorrected (e.g. uncorrectable) error. In an embodiment, a count of corrected errors may continue to be incremented even after an uncorrected error has been logged.

Registration logic 320 (or other such logic of the memory device) may implement one or more rules which determine whether and/or how state information in a mode register is to be overwritten or otherwise updated. By way of illustration and not limitation, such logic may implement an overwrite rule requiring that state information for a corrected error cannot overwrite state information for an uncorrected error. Alternatively or in addition, such an overwrite rule may require that state information for an uncorrected error does not overwrite state information for another uncorrected error.

In an embodiment, uncorrectable errors are indicated to a memory controller for some or all read transactions—e.g. via an external I/O contact (e.g. pin, pad, ball or the like) of the memory device. Such an external I/O contact pin may be dedicated to reporting uncorrectable errors. Alternatively, such an external I/O contact may further serve one or more other signal functions in the memory, for example, via a multiplexer. In an embodiment, the state of a given mode register bit—e.g. an RFU bit in mode register MRz 430—may enable the communication of a signal to indicate an error to the memory controller. Such a signal may be communicated—for example, during a read transaction from the memory die to the memory controller—to indicate one or more uncorrectable errors.

Such an external I/O contact may be adapted, for example, from Data Mask (DM), Data Bus Inversion (DBI) and/or similar communication techniques such as those of LPDDR4 and/or Wide Input/Output version 2 (WIO2). For example, in conventional LPDDR4, a DRAM inverts read data on its Data Input/Output (DQ) outputs associated within a byte and drives its DBI signal HIGH when the number of “1” data bits to be read within a given byte lane is greater than four. Otherwise, the DRAM does not invert such read data bits and instead drives DBI signal LOW. By contrast, in certain embodiments, a memory device indicates a data error to a memory controller by asserting a logic HIGH signal on a DBI signal line in association with an eight bit data transfer which includes five “1” bits. In conventional DRAM specifications which support DBI, such a combination of DBI and data bits is an illegal condition. However, certain embodiments adapt such a condition to support the indicating of data errors to the memory controller. For example, a DM signal line, DBI signal line or other such control signal line may be adapted to indicate during a read transfer that data being exchanged in the read transfer includes an error—e.g. wherein it is indicated that the error is uncorrectable. In an embodiment, a signal may be asserted HIGH on a DBI signal line for the length of a read data transfer. Alternatively, such a signal may be pulsed for couple of clock cycles, multiple times for each unit interval (UI) of a read transfer, or the like. For a Dual Data Rate (DDR) memory, a unit interval is half the clock period. For a Single Data Rate (SDR) memory, the unit interval is a clock period.

In an embodiment, a mode register includes an EDC enable bit which the memory controller may set to selectively enable/disable internal error detection and/or correction functionality of the memory device. Alternatively or in addition, a mode register may include an EDC_present bit—e.g. which the memory controller may only read—to allow the memory controller to determine if the DRAM supports such internal error detection and/or correction functionality.

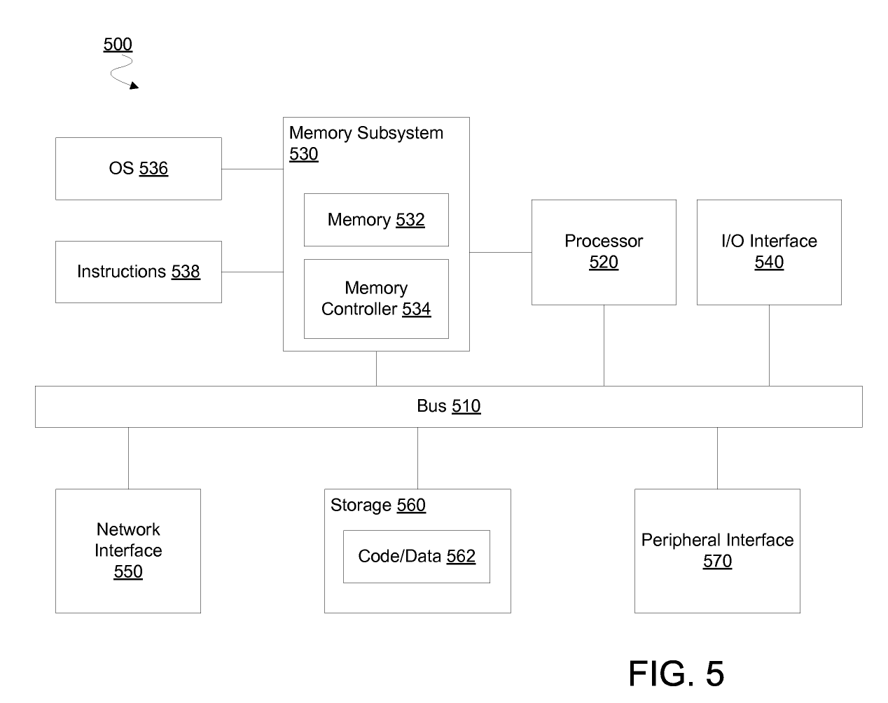

FIG. 5 is a block diagram of an embodiment of a computing system in which error detection may be implemented. System 500 represents a computing device in accordance with any embodiment described herein, and may be a laptop computer, a desktop computer, a server, a gaming or entertainment control system, a scanner, copier, printer, or other electronic device. System 500 may include processor 520, which provides processing, operation management, and execution of instructions for system 500. Processor 520 may include any type of microprocessor, central processing unit (CPU), processing core, or other processing hardware to provide processing for system 500. Processor 520 controls the overall operation of system 500, and may be or include, one or more programmable general-purpose or special-purpose microprocessors, digital signal processors (DSPs), programmable controllers, application specific integrated circuits (ASICs), programmable logic devices (PLDs), or the like, or a combination of such devices.

Memory subsystem 530 represents the main memory of system 500, and provides temporary storage for code to be executed by processor 520, or data values to be used in executing a routine. Memory subsystem 530 may include one or more memory devices such as read-only memory (ROM), flash memory, one or more varieties of random access memory (RAM), or other memory devices, or a combination of such devices. Memory subsystem 530 stores and hosts, among other things, operating system (OS) 536 to provide a software platform for execution of instructions in system 500. Additionally, other instructions 538 are stored and executed from memory subsystem 530 to provide the logic and the processing of system 500. OS 536 and instructions 538 are executed by processor 520.

Memory subsystem 530 may include memory device 532 where it stores data, instructions, programs, or other items. In one embodiment, memory subsystem includes memory controller 534, which is a memory controller in accordance with any embodiment described herein, and which provides mechanisms for monitoring performance of memory device 532. In one embodiment, memory controller 534 provides commands to memory device 532. The commands may be for memory device 532 to provide state information describing one or more data errors detected (and in some embodiments, corrected) locally at memory device 532.

Processor 520 and memory subsystem 530 are coupled to bus/bus system 510. Bus 510 is an abstraction that represents any one or more separate physical buses, communication lines/interfaces, and/or point-to-point connections, connected by appropriate bridges, adapters, and/or controllers. Therefore, bus 510 may include, for example, one or more of a system bus, a Peripheral Component Interconnect (PCI) bus, a HyperTransport or industry standard architecture (ISA) bus, a small computer system interface (SCSI) bus, a universal serial bus (USB), or an Institute of Electrical and Electronics Engineers (IEEE) standard 1394 bus (commonly referred to as “Firewire”). The buses of bus 510 may also correspond to interfaces in network interface 550.

System 500 may also include one or more input/output (I/O) interface(s) 540, network interface 550, one or more internal mass storage device(s) 560, and peripheral interface 570 coupled to bus 510. I/O interface 540 may include one or more interface components through which a user interacts with system 500 (e.g., video, audio, and/or alphanumeric interfacing). Network interface 550 provides system 500 the ability to communicate with remote devices (e.g., servers, other computing devices) over one or more networks. Network interface 550 may include an Ethernet adapter, wireless interconnection components, USB (universal serial bus), or other wired or wireless standards-based or proprietary interfaces.

Storage 560 may be or include any conventional medium for storing large amounts of data in a nonvolatile manner, such as one or more magnetic, solid state, or optical based disks, or a combination. Storage 560 holds code or instructions and data 562 in a persistent state (i.e., the value is retained despite interruption of power to system 500). Storage 560 may be generically considered to be a “memory,” although memory 530 is the executing or operating memory to provide instructions to processor 520. Whereas storage 560 is nonvolatile, memory 530 may include volatile memory (i.e., the value or state of the data is indeterminate if power is interrupted to system 500).

Peripheral interface 570 may include any hardware interface not specifically mentioned above. Peripherals refer generally to devices that connect dependently to system 500. A dependent connection is one where system 500 provides the software and/or hardware platform on which operation executes, and with which a user interacts.

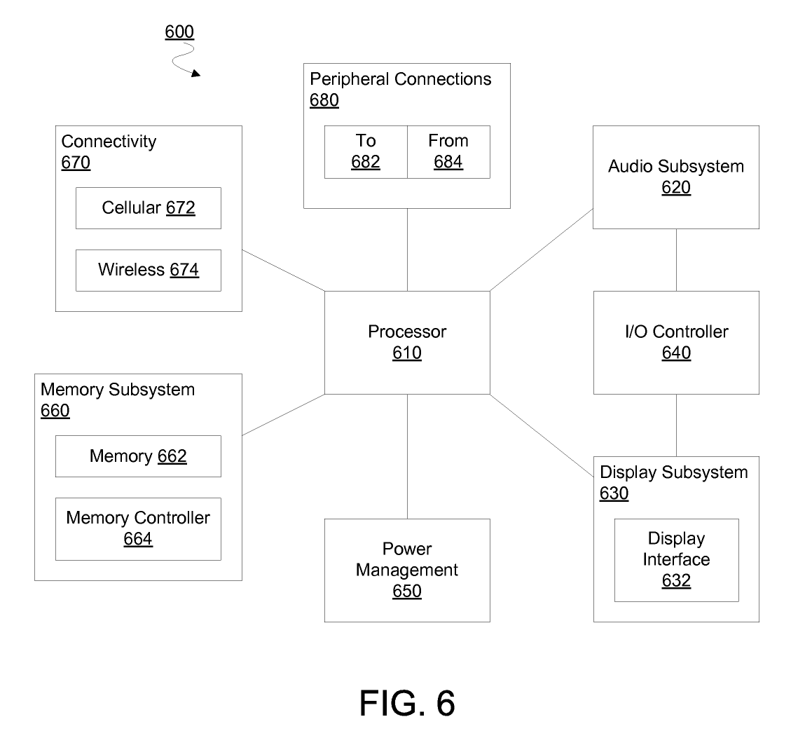

FIG. 6 is a block diagram of an embodiment of a mobile device in which error detection may be implemented. Device 600 represents a mobile computing device, such as a computing tablet, a mobile phone or smartphone, a wireless-enabled e-reader, or other mobile device. It will be understood that certain of the components are shown generally, and not all components of such a device are shown in device 600.

Device 600 may include processor 610, which performs the primary processing operations of device 600. Processor 610 may include one or more physical devices, such as microprocessors, application processors, microcontrollers, programmable logic devices, or other processing means. The processing operations performed by processor 610 include the execution of an operating platform or operating system on which applications and/or device functions are executed. The processing operations include operations related to I/O (input/output) with a human user or with other devices, operations related to power management, and/or operations related to connecting device 600 to another device. The processing operations may also include operations related to audio I/O and/or display I/O.

In one embodiment, device 600 includes audio subsystem 620, which represents hardware (e.g., audio hardware and audio circuits) and software (e.g., drivers, codecs) components associated with providing audio functions to the computing device. Audio functions may include speaker and/or headphone output, as well as microphone input. Devices for such functions may be integrated into device 600, or connected to device 600. In one embodiment, a user interacts with device 600 by providing audio commands that are received and processed by processor 610.

Display subsystem 630 represents hardware (e.g., display devices) and software (e.g., drivers) components that provide a visual and/or tactile display for a user to interact with the computing device. Display subsystem 630 may include display interface 632, which may include the particular screen or hardware device used to provide a display to a user. In one embodiment, display interface 632 includes logic separate from processor 610 to perform at least some processing related to the display. In one embodiment, display subsystem 630 includes a touchscreen device that provides both output and input to a user.

I/O controller 640 represents hardware devices and software components related to interaction with a user. I/O controller 640 may operate to manage hardware that is part of audio subsystem 620 and/or display subsystem 630. Additionally, I/O controller 640 illustrates a connection point for additional devices that connect to device 600 through which a user might interact with the system. For example, devices that may be attached to device 600 might include microphone devices, speaker or stereo systems, video systems or other display device, keyboard or keypad devices, or other I/O devices for use with specific applications such as card readers or other devices.

As mentioned above, I/O controller 640 may interact with audio subsystem 620 and/or display subsystem 630. For example, input through a microphone or other audio device may provide input or commands for one or more applications or functions of device 600. Additionally, audio output may be provided instead of or in addition to display output. In another example, if display subsystem includes a touchscreen, the display device also acts as an input device, which may be at least partially managed by I/O controller 640. There may also be additional buttons or switches on device 600 to provide I/O functions managed by I/O controller 640.

In one embodiment, I/O controller 640 manages devices such as accelerometers, cameras, light sensors or other environmental sensors, gyroscopes, global positioning system (GPS), or other hardware that may be included in device 600. The input may be part of direct user interaction, as well as providing environmental input to the system to influence its operations (such as filtering for noise, adjusting displays for brightness detection, applying a flash for a camera, or other features).

In one embodiment, device 600 includes power management 650 that manages battery power usage, charging of the battery, and features related to power saving operation. Memory subsystem 660 may include memory device(s) 662 for storing information in device 600. Memory subsystem 660 may include nonvolatile (state does not change if power to the memory device is interrupted) and/or volatile (state is indeterminate if power to the memory device is interrupted) memory devices. Memory 660 may store application data, user data, music, photos, documents, or other data, as well as system data (whether long-term or temporary) related to the execution of the applications and functions of system 600.

In one embodiment, memory subsystem 660 includes memory controller 664 (which could also be considered part of the control of system 600, and could potentially be considered part of processor 610). Memory controller 664 monitors performance of memory 662. For example, memory controller 664 may detect a signal from memory 662 indicating that memory 662 to has detected (and in some embodiments, corrected) one or more data errors. In response to such a signal, memory controller 664 may issue a command for memory 662 to provide state information describing such one or more data errors.

Connectivity 670 may include hardware devices (e.g., wireless and/or wired connectors and communication hardware) and software components (e.g., drivers, protocol stacks) to enable device 600 to communicate with external devices. The device could be separate devices, such as other computing devices, wireless access points or base stations, as well as peripherals such as headsets, printers, or other devices.

Connectivity 670 may include multiple different types of connectivity. To generalize, device 600 is illustrated with cellular connectivity 672 and wireless connectivity 674. Cellular connectivity 672 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, LTE (long term evolution—also referred to as “4G”), or other cellular service standards. Wireless connectivity 674 refers to wireless connectivity that is not cellular, and may include personal area networks (such as Bluetooth), local area networks (such as WiFi), and/or wide area networks (such as WiMax), or other wireless communication. Wireless communication refers to transfer of data through the use of modulated electromagnetic radiation through a non-solid medium. Wired communication occurs through a solid communication medium.

Peripheral connections 680 include hardware interfaces and connectors, as well as software components (e.g., drivers, protocol stacks) to make peripheral connections. It will be understood that device 600 could both be a peripheral device (“to” 682) to other computing devices, as well as have peripheral devices (“from” 684) connected to it. Device 600 commonly has a “docking” connector to connect to other computing devices for purposes such as managing (e.g., downloading and/or uploading, changing, synchronizing) content on device 600. Additionally, a docking connector may allow device 600 to connect to certain peripherals that allow device 600 to control content output, for example, to audiovisual or other systems.

In addition to a proprietary docking connector or other proprietary connection hardware, device 600 may make peripheral connections 680 via common or standards-based connectors. Common types may include a Universal Serial Bus (USB) connector (which may include any of a number of different hardware interfaces), DisplayPort including MiniDisplayPort (MDP), High Definition Multimedia Interface (HDMI), Firewire, or other type.

In one implementation, a memory device comprises one or more registers, a memory core including circuitry configured to store first data bits at a memory core, and error detection logic including circuitry configured to detect an error of the first data bits based on one or more error check bits corresponding to the first data bits, wherein a die of the memory device includes the memory core and the error detection logic In response to the error, the error detection logic is to correct the error, including the error detection logic to calculate corrected first data bits, and to store at one or more registers state information other than the corrected first data bits, the state information indicating an occurrence of the error. The memory device further comprises access logic configured to service a command from a memory controller to access the state information stored at the one or more registers.

In an embodiment, the access logic to service the command includes the access logic to send the state information from the memory device to the memory controller. In another embodiment, the access logic to service the command includes the access logic to reset a count of errors to a default value. In another embodiment, the memory core is further to store the one or more error check bits. In another embodiment, the memory core is to store the first data bits at a first memory location, wherein the state information includes first address information corresponding to the first memory location. In another embodiment, the first address information includes bank address information. In another embodiment, the first address information includes row address information or column address information. In another embodiment, the error detection logic to store the state information includes the error detection logic to update a count of errors. In another embodiment, the access logic is further to service a read command from the memory controller, wherein the access logic is to transfer to the memory controller both data and a control signal based on the state information, the control signal to indicate to the memory controller that the data includes an error.

In another implementation, a method at a memory device comprises storing first data bits at a memory core, and detecting an error of the first data bits, including detecting the error with error detection logic based on one or more error check bits corresponding to the first data bits, wherein a die of the memory device includes the memory core and the error detection logic. The method further comprises, in response to detecting the error, correcting the error with the error detection logic, including calculating corrected first data bits, and storing at one or more registers of the memory device state information other than the corrected first data bits, the state information indicating an occurrence of the error. The method further comprises, after storing the state information, servicing a command from a memory controller to access the state information.

In an embodiment, servicing the command includes sending the state information from the memory device to the memory controller. In another embodiment, servicing the command includes resetting a count of errors to a default value. In another embodiment, the method further comprises storing the one or more error check bits at the memory core. In another embodiment, storing the first data bits includes storing at a first memory location of the memory core, wherein the state information includes first address information corresponding to the first memory location. In another embodiment, the first address information includes bank address information. In another embodiment, the first address information includes row address information or column address information. In another embodiment, storing the state information includes updating a count of errors. In another embodiment, the method further comprises servicing a read command from the memory controller, including transferring to the memory controller both data and a control signal based on the state information, the control signal indicating to the memory controller that the data includes an error.

In another implementation, a memory controller comprises command logic including circuitry configured to send from the memory controller to a memory device a command to access state information indicating an occurrence of an error of first data bits stored by a memory core, the state information stored at one or more registers of the memory device in response to detection of the error by error detection logic based on one or more error check bits, wherein a die of the memory device includes the memory core and the error detection logic, and wherein the error detection logic calculates corrected first data bits other than the state information to correct the error. The memory controller further comprises monitor logic configured to receive the state information in response to the command and to evaluate a performance of the memory device based on the state information.

In an embodiment, the monitor logic is further to reset a count of errors stored at the one or more registers. In another embodiment, the memory core stores the first data bits at a first memory location, wherein the state information includes first address information corresponding to the first memory location. In another embodiment, the first address information includes bank address information. In another embodiment, the first address information includes row address information or column address information.

In another implementation, a method at a memory controller comprises sending from the memory controller to a memory device a command to access state information indicating an occurrence of an error of first data bits stored by a memory core, the state information stored at one or more registers of the memory device in response to detection of the error by error detection logic based on one or more error check bits, wherein a die of the memory device includes the memory core and the error detection logic, and wherein the error detection logic calculates corrected first data bits other than the state information to correct the error. The method further comprises receiving the state information in response to the command, and evaluating a performance of the memory device based on the state information. In an embodiment, the method further comprises resetting a count of errors stored at the one or more registers. In another embodiment, the memory core stores the first data bits at a first memory location, wherein the state information includes first address information corresponding to the first memory location. In another embodiment, the first address information includes bank address information. In another embodiment, the first address information includes row address information or column address information.

Techniques and architectures for providing error detection information are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

What is claimed is:

1. A memory device comprising:
one or more registers;
a memory core including circuitry configured to store first data bits at a memory core;
error detection logic including circuitry configured to detect an error of the first data bits based on one or more error check bits corresponding to the first data bits, wherein a die of the memory device includes the memory core and the error detection logic, wherein, in response to the error, the error detection logic:
to correct the error, including the error detection logic to calculate corrected first data bits; and
to store at one or more registers state information other than the corrected first data bits, the state information indicating an occurrence of the error; and
access logic configured to service a command from a memory controller to access the state information stored at the one or more registers.

2. The memory device of claim 1, wherein the access logic to service the command includes the access logic to send the state information from the memory device to the memory controller.

3. The memory device of claim 1, wherein the access logic to service the command includes the access logic to reset a count of errors to a default value.

4. The memory device of claim 1, the memory core further to store the one or more error check bits.

5. The memory device of claim 1, wherein the memory core to store the first data bits at a first memory location, wherein the state information includes first address information corresponding to the first memory location.

6. The memory device of claim 5, wherein the first address information includes bank address information.

7. The memory device of claim 5, wherein the first address information includes row address information or column address information.

8. The memory device of claim 1, wherein the error detection logic to store the state information includes the error detection logic to update a count of errors.

9. The memory device of claim 1, the access logic further to service a read command from the memory controller, wherein the access logic to transfer to the memory controller both data and a control signal based on the state information, the control signal to indicate to the memory controller that the data includes an error.

10. A method at a memory device, the method comprising:
storing first data bits at a memory core;
detecting an error of the first data bits, including detecting the error with error detection logic based on one or more error check bits corresponding to the first data bits, wherein a die of the memory device includes the memory core and the error detection logic;
in response to detecting the error:
correcting the error with the error detection logic, including calculating corrected first data bits; and
storing at one or more registers of the memory device state information other than the corrected first data bits, the state information indicating an occurrence of the error; and
after storing the state information, servicing a command from a memory controller to access the state information.

11. The method of claim 10, wherein servicing the command includes sending the state information from the memory device to the memory controller.

12. The method of claim 10, wherein servicing the command includes resetting a count of errors to a default value.

13. The method of claim 10, further comprising storing the one or more error check bits at the memory core.

14. The method of claim 10, wherein storing the first data bits includes storing at a first memory location of the memory core, wherein the state information includes first address information corresponding to the first memory location.

15. The method of claim 10, wherein the storing the state information includes updating a count of errors.

16. The method of claim 10, further comprising:
servicing a read command from the memory controller, including transferring to the memory controller both data and a control signal based on the state information, the control signal indicating to the memory controller that the data includes an error.

17. A memory controller comprising:
command logic including circuitry configured to send from the memory controller to a memory device a command to access state information indicating an occurrence of an error of first data bits stored by a memory core, the state information stored at one or more registers of the memory device in response to detection of the error by error detection logic based on one or more error check bits, wherein a die of the memory device includes the memory core and the error detection logic, and wherein the error detection logic calculates corrected first data bits other than the state information to correct the error; and
monitor logic configured to receive the state information in response to the command and to evaluate a performance of the memory device based on the state information.

18. The memory controller of claim 17, the monitor logic further to reset a count of errors stored at the one or more registers.

19. The memory controller of claim 17, wherein the memory core stores the first data bits at a first memory location, and wherein the state information includes first address information corresponding to the first memory location.

20. The memory controller of claim 19, wherein the first address information includes bank address information.

21. A method at a memory controller, the method comprising:
sending from the memory controller to a memory device a command to access state information indicating an occurrence of an error of first data bits stored by a memory core, the state information stored at one or more registers of the memory device in response to detection of the error by error detection logic based on one or more error check bits, wherein a die of the memory device includes the memory core and the error detection logic, and wherein the error detection logic calculates corrected first data bits other than the state information to correct the error; and
receiving the state information in response to the command;
evaluating a performance of the memory device based on the state information.

22. The method of claim 21, further comprising resetting a count of errors stored at the one or more registers.

23. The method of claim 21, wherein the memory core stores the first data bits at a first memory location, and wherein the state information includes first address information corresponding to the first memory location.

24. The method of claim 21, wherein the first address information includes bank address information.
